(19) United States
(12) Patent Application Publication
(10) Pub. No.: US 2024/0266478 A1
(43) Pub. Date: Aug. 8, 2024

(54) LUMIPHORIC PARTICLE STRUCTURES IN WAVELENGTH CONVERSION ELEMENTS FOR LIGHT-EMITTING DIODES AND RELATED METHODS

(71) Applicant: CreeLED, Inc., Durham, NC (US)

(72) Inventors: Andre Pertuit, Raleigh, NC (US); Michael Check, Holly Springs, NC (US); David Suich, Durham, NC (US); Colin Blakely, Raleigh, NC (US); Robert Wilcox, Rolesville, NC (US)

(21) Appl. No.: 18/163,396

(22) Filed: Feb. 2, 2023

(51) Int. Cl. H01L 33/50; H01L 33/60

(52) U.S. Cl. CPC H01L 33/504; H01L 33/60; H01L 2933/0041; H01L 2933/0058

(57) ABSTRACT

Solid-state lighting devices including light-emitting diodes (LEDs) and more particularly lumiphoric particle structures in wavelength conversion elements for LEDs and related methods are disclosed. Lumiphoric particle structures include coatings that provide improved optical, mechanical, and/or thermal characteristics when distributed within host materials of wavelength conversion elements. Coatings are pre-formed on lumiphoric particles before the lumiphoric particles are integrated with wavelength conversion elements. Heat treatments associated with firing wavelength conversion elements may diffuse coating materials within wavelength conversion elements to form graded material structures for further improvements to optical, mechanical, and/or thermal characteristics.

### FIELD OF THE DISCLOSURE

The present disclosure relates to solid-state lighting devices including light-emitting diodes (LEDs) and more particularly to lumiphoric particle structures in wavelength conversion elements for LEDs and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions. Lumiphoric materials may be arranged that convert at least some light generated from the active regions of LED chips to a different wavelength.

LED packages have been developed that provide mechanical support, electrical connections, and encapsulation for LED emitters and lumiphoric materials. As LED technology continues to advance, LED packages are needed that emit light of high color quality for various applications. Despite recent advances in LED package technology, challenges remain for producing high quality light with desired emission characteristics while also providing high light emission efficiency in LED packages.

The art continues to seek improved LEDs and solid-state lighting devices having desirable illumination characteristics capable of overcoming challenges associated with conventional LED devices.

### SUMMARY

The present disclosure relates to solid-state lighting devices including light-emitting diodes (LEDs) and more particularly to lumiphoric particle structures in wavelength conversion elements for LEDs and related methods. Lumiphoric particle structures include coatings that provide improved optical, mechanical, and/or thermal characteristics when distributed within host materials of wavelength conversion elements. Coatings are pre-formed on lumiphoric particles before the lumiphoric particles are integrated with wavelength conversion elements. Heat treatments associated with firing wavelength conversion elements may diffuse coating materials within wavelength conversion elements to form graded material structures for further improvements to optical, mechanical, and/or thermal characteristics.

In one aspect, a method comprises: forming a coating of a first material on one or more lumiphoric particles; suspending the one or more lumiphoric particles in a host material; and firing the host material with the one or more lumiphoric particles such that the first material of the coating radially diffuses into the host material around the one or more lumiphoric particles, the host material and the one or more lumiphoric particles forming a wavelength conversion element. The method may further comprise singulating the wavelength conversion into a number of individual wavelength conversion elements. In certain embodiments, the first material of the coating comprises a first glass material and the host material comprises a second glass material that is different than the first glass material.

In certain embodiments, the coating is a first coating of the first material and the one or more lumiphoric particles are one or more first lumiphoric particles, the method further comprising: forming a second coating of a second material on one or more second lumiphoric particles; suspending the one or more first lumiphoric particles and the one or more second lumiphoric particles in the host material; and firing the host material with the one or more first lumiphoric particles and the one or more second lumiphoric particles to form the wavelength conversion element.

In certain embodiments, the method further comprises attaching the wavelength conversion element to a light-emitting diode (LED) chip. In certain embodiments, the method further comprises mounting the LED chip to a submount such that the LED chip is between the wavelength conversion element and the submount. In certain embodiments, the method further comprises forming a light-reflective or light-refractive material on the submount and laterally surrounding peripheral edges of the LED chip and the wavelength conversion element. In certain embodiments, the one or more lumiphoric particles comprises a plurality of lumiphoric particles and the coating surrounds at least two lumiphoric particles of the plurality of lumiphoric particles. In certain embodiments, firing the host material comprises vacuum drying. In certain embodiments, firing the host material comprises heating the host material with the one or more lumiphoric particles and the coating.

In another aspect, an LED package comprises: at least one LED chip, the at least one LED chip being configured to generate light in a first peak wavelength range; and a wavelength conversion element on the at least one LED chip, the wavelength conversion element comprising a plurality of lumiphoric particles in a host material and a plurality of coatings forming intermediate materials between the plurality of lumiphoric particles and the host material, and an individual coating of the plurality of coatings surrounds at least one individual lumiphoric particle of the plurality of lumiphoric particles. In certain embodiments, the individual coating of the plurality of coatings surrounds at least two lumiphoric particles of the plurality of lumiphoric particles. In certain embodiments, each lumiphoric particle of the plurality of lumiphoric particles is surrounded by at least one coating of the plurality of coatings. In certain embodiments, neighboring lumiphoric particles of the plurality of lumiphoric particles and corresponding coatings of the plurality of coatings are separated by portions of the host material.

In certain embodiments, the plurality of lumiphoric particles comprise: a first lumiphoric particle configured to convert a first wavelength of light from the at least one LED chip to a second wavelength of light, and a first coating of the plurality of coatings is arranged to encapsulate the first lumiphoric particle; and a second lumiphoric particle configured to convert the first wavelength of light from the at least one LED chip to a third wavelength of light that is different than the second wavelength of light, and a second coating of the plurality of coatings is arranged to encapsulate the second lumiphoric particle, wherein the second coating comprises a different material than the first coating. In certain embodiments, the plurality of coatings form graded structures within the wavelength conversion element such that a concentration of the intermediate materials decreases in directions away from each lumiphoric particle of the plurality of lumiphoric particles.

In certain embodiments, the host material comprises a first glass material. In certain embodiments, the plurality of coatings comprises a second glass material that is different than the first glass material. In certain embodiments, the host material comprises a ceramic material. The LED package may further comprise a submount on which the at least one LED chip is mounted, and a light-reflective or light-refractive material on the submount and laterally surrounding peripheral edges of the at least one LED chip and the wavelength conversion element. In certain embodiments, the individual coating of the plurality of coatings comprises a multiple-layer structure on the at least one individual lumiphoric particle.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) package that includes an LED chip with a wavelength conversion element that includes lumiphoric particles with coatings according to aspects disclosed herein.

FIG. 2 is a cross-sectional view of a portion of the wavelength conversion element of FIG. 1 with an individual lumiphoric particle and corresponding coating.

FIG. 3 is a cross-sectional view of a portion of the wavelength conversion element of FIG. 1 for embodiments that include different types of lumiphoric particles.

FIG. 4 is a cross-sectional view depicting embodiments where material grading of pre-formed coatings is promoted when formed within the wavelength conversion element.

FIG. 5 is a cross-sectional view of an LED package that is similar to the LED package of FIG. 1 for embodiments where the coatings form graded material structures.

FIG. 6A is a cross-sectional view of lumiphoric particles at a fabrication step where corresponding coatings are formed on the lumiphoric particles.

FIG. 6B is a cross-sectional view at a subsequent fabrication step to FIG. 6A where the lumiphoric particles and coatings are suspended within a host material for forming a wavelength conversion element.

FIG. 6C is a cross-sectional view at a subsequent fabrication step to FIG. 6B where the wavelength conversion element has been fired and materials of the coatings are diffused within the host materials to form graded material structures.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to lumiphoric particle structures in wavelength conversion elements for LEDs and related methods. Lumiphoric particle structures include coatings that provide improved optical, mechanical, and/or thermal characteristics when distributed within host materials of wavelength conversion elements. Coatings are pre-formed on lumiphoric particles before the lumiphoric particles are integrated with wavelength conversion elements. Heat treatments associated with firing wavelength conversion elements may diffuse coating materials within wavelength conversion elements to form graded material structures for further improvements to optical, mechanical, and/or thermal characteristics.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (AI), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include silicon carbide (SiC), organic semiconductor materials, and other Group Ill-V systems such as gallium phosphide (GaP), gallium arsenide (GaAs), and related compounds. The active LED structure may be grown on a growth substrate that can include many materials, such as sapphire, SiC, aluminum nitride (AlN), and GaN.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. Other wavelength ranges include a range from 400 nm to about 430 nm and/or a range from 480 nm to 500 nm, among others, or any wavelength in a range from 400 nm to 750 nm. In certain embodiments, the active LED structure may be configured to emit light that is outside the visible spectrum, including one or more portions of the ultraviolet (UV) spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are provided from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate.

According to aspects of the present disclosure, LED packages may include one or more elements, such as cover structures with lumiphoric materials or phosphors for wavelength conversion, encapsulants, light-altering materials, lenses, and electrical contacts, among others, that are provided with one or more LED chips. In certain aspects, an LED package may include a support structure or member, such as a submount or a lead frame. A support structure may refer to a structure of an LED package that supports one or more other elements of the LED package, including but not limited to LED chips and cover structures. In certain embodiments, a support structure may include a submount on which an LED chip is mounted. Suitable materials for a submount include, but are not limited to, ceramic materials such as aluminum oxide or alumina, AlN, or organic insulators like polyimide (PI) and polyphthalamide (PPA). In other embodiments a submount may comprise a printed circuit board (PCB), sapphire, Si, or any other suitable material. For PCB embodiments, different PCB types can be used such as standard FR-4 PCB, metal core PCB, or any other type of PCB. In still further embodiments, the support structure may embody a lead frame structure. Aspects of the present disclosure are provided in the context of support structures for LED chips that may emit light in any number of wavelength ranges, including wavelengths within UV and/or visible light spectrums.

Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

An LED chip can also be covered or otherwise arranged to emit light toward one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500 Kelvin (K) to 10,000K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, dispersal of particles in a host material or an encapsulant material. In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied relative to one or more outer surfaces of an LED chip. In certain embodiments, one or more lumiphoric materials may be patterned relative to one or more surfaces of an LED chip to include one or more stripes, dots, curves, or polygonal shapes. In certain embodiments, multiple lumiphoric materials may be arranged in different discrete regions or discrete layers on or over an LED chip.

In certain embodiments, one or more lumiphoric materials may be provided as at least a portion of a wavelength conversion element or a cover structure for an LED package. Wavelength conversion elements or cover structures may include phosphor-in-glass arrangements formed by mixing phosphor particles with glass frit or ceramic materials, pressing the mixture into planar shapes, and firing or sintering the mixture to form a hardened structure that can be cut or separated into individual wavelength conversion elements. For certain phosphor-in-glass arrangements, multiple sheets of precursor materials, such as glass frit and a corresponding binder, may be laminated and fired together. Wavelength conversion elements may be attached to one or more LED chips using, for example, a layer of transparent adhesive. In certain embodiments, the layer of the transparent adhesive may include silicone with a refractive index in a range of about 1.3 to about 1.6 that is less than a refractive index of the LED chip on which the wavelength conversion element is placed.

Aspects of the present disclosure may include specific arrangements of lumiphoric particles that may be provided within cover structures for LED packages for altering and/or improving emission characteristics. Such cover structures may include hard and mechanically robust structures that are positioned over one or more LED chips within an LED package. Cover structures may be formed of glass material, such as glass frit and/or laminated sheets of glass frit, or various ceramic materials. As will be further described with regard to specific embodiments, lumiphoric materials may be provided as a distribution of particles within such cover structures. When lumiphoric materials are present, cover structures may also be referred to as wavelength conversion elements. A cover structure may be configured to provide protection from environmental exposure to underlying portions of an LED package, thereby providing a more robust LED package that is well suited for applications that require high power with increased light intensity, contrast, and reliability, such as interior and exterior automotive applications.

Aspects of the present disclosure relate to structures of lumiphoric particles that provide improved optical, mechanical, and/or thermal characteristics when distributed within a host or binder material. The lumiphoric particles may be coated by way of chemical treatments and/or glass coatings before being distributed in host materials of cover structures or wavelength conversion elements. By effectively pre-coating the lumiphoric particles before they are incorporated within wavelength conversion elements, the material of the coatings may be selected to tailor various optical, mechanical, and/or thermal characteristics of the wavelength conversion elements. For example, materials of coatings may be selected to form an index of refraction step between the lumiphoric particles and the host material, thereby providing increased wavelength conversion efficiency by increasing transmission of blue light that interacts with the lumiphoric particles. The coating material may also be selected to provide enhanced protection of lumiphoric particles, thereby reducing degradation of the lumiphoric particles within the wavelength conversion element. In still further examples, the coating material may be selected to increase thermal conductivity in the host material proximate the lumiphoric particles. In such examples, reliability and/or efficiency of wavelength conversion may be improved by effectively drawing more heat away from each lumiphoric particle. In still further examples, the coating material may include dopant materials configured to alter properties of the host material, such as any of the optical, mechanical, and/or thermal properties discussed above. In any of the above embodiments, the material of the coating may locally diffuse into the host material during firing or hardening of the wavelength conversion elements. In this regard, wavelength conversion elements may include lumiphoric particles and intermediate materials from the coatings that form graded material structures between the lumiphoric particles and other portions of the hardened host material.

Coatings for lumiphoric particles may be formed by a number of techniques. For example, lumiphoric particles may be contacted with a solution or sol-gel containing a material or one or more precursor materials that form the coating, followed by a drying and/or heating step that forms the coated lumiphoric particles. When precursor materials are used, some examples involve reacting the precursor materials in the presence of the lumiphoric particles to form the coatings. Coatings may be applied via dip-coating, spread-coating, spray coating, spin coating, brushing, absorption, rolling, and electrodeposition. Coated lumiphoric particles may be subjected to vacuum drying, photocuring, and/or thermal curing. Other coatings for lumiphoric particles may be formed by passivating surfaces thereof, such as oxidation of lumiphoric particle surfaces. Still other coatings may be achieved by chemical reactions of precursor materials with materials of the lumiphoric particles. In various embodiments, coating steps may be performed once or repeated a number of times to achieve desired thicknesses and/or coverage. Exemplary materials for coatings may include inorganic coatings, glass, silicates, silica oxides, alumina, borate, polymers, pre-ceramic polymers, tetramethyl orthosilicate (TMOS), and fluorides, among others.

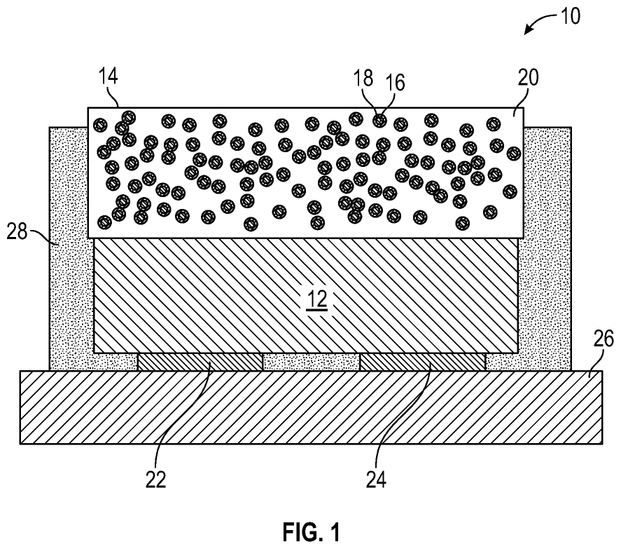

FIG. 1 is a cross-sectional view of an LED package 10 that includes an LED chip 12 with a wavelength conversion element 14 that includes lumiphoric particles 16 with coatings 18 according to aspects disclosed herein. As illustrated, the lumiphoric particles 16 are embedded or otherwise dispersed within the wavelength conversion element 14. For example, a base or host material 20 of the wavelength conversion element 14 may include glass and the lumiphoric particles 16 are distributed throughout the glass. In other embodiments, the host material 20 may comprise one or more ceramic materials. By incorporating the lumiphoric particles 16 within the wavelength conversion element 14, rather than as a separate film or coating, the host material 20 of the wavelength conversion element 14 may effectively provide encapsulation and environmental protection for the lumiphoric particles 16. As illustrated, the lumiphoric particles 16 may comprise coatings 18 that form barriers between the lumiphoric particles 16 and the host material 20. The coatings 18 may be formed on lumiphoric particles 16 before the lumiphoric particles 16 are dispersed within the host material 20. In this manner, the coatings 18 form intermediate materials between the lumiphoric particles 16 and the host material 20. The selection of materials for the coatings 18 may thereby alter characteristics of the wavelength conversion element 14 in a localized manner proximate the lumiphoric particles 16. By way of example, the host material 20 may comprise a first glass material and the coatings 18 may comprise a second glass material that includes at least one different element, material, compound, and/or dopant than the first glass material. As described above, altered characteristics include improved optical, mechanical, and/or thermal characteristics. Individual ones of the lumiphoric particles 16 may be surrounded or fully encapsulated by a corresponding coating 18 with portions of the host material 20 separating neighboring ones of the lumiphoric particles 16 and corresponding coatings 18. Additionally, some lumiphoric particles 16 may clump together with a continuous coating 18 that effectively encapsulates multiple lumiphoric particles 16. Since the lumiphoric particles 16 are pre-coated with the coatings 18, the material of the coatings 18 remains immediately adjacent the lumiphoric particles 16 after firing of the host material 20 to harden the wavelength conversion element 14.

In certain embodiments, each of the lumiphoric particles 16 may comprise a same type of particle, such as a phosphor particle that provides a same color spectrum of light. In other embodiments, the lumiphoric particles 16 may include at least two, or at least three, or many different types of particles, such as different phosphor particles configured to provide different color spectrums of light. In certain embodiments, the coatings 18 may also be formed of different material types. For example, certain ones of the lumiphoric particles 16 may include yellow phosphor particles and others of the lumiphoric particles 16 may include red or green phosphor particles. The corresponding coatings 18 may be chosen based on the specific phosphor particles, such as a material with increased thermal conductivity for the red phosphor particle compared to the yellow phosphor particle.

With continued reference to FIG. 1, the LED chip 12 may have a flip-chip orientation such that an anode contact 22 and a cathode contact 24 are accessible from a same side of the LED chip 12 for flip-chip mounting to a submount 26. The submount 26 typically includes corresponding electrical traces for routing electrical connections to the LED chip 12. While a single LED chip 12 is illustrated, a plurality of LED chips 12 could be mounted on the submount 26, each with their own wavelength conversion element 14, or beneath a common wavelength conversion element 14 for multiple LED chips. The LED package 10 may further include a light-altering layer 28 arranged on the submount 26 and surrounding lateral edges of the LED chip 12. The light-altering layer 28 may include a light-reflective material and/or a light-refracting material that effectively redirects laterally propagating light back toward a desired emission direction, such as through the wavelength conversion element 14. In certain embodiments, the light-altering layer 28 may also surround lateral edges of the wavelength conversion element 14. In this manner, the wavelength conversion element 14 forms the emission surface of the LED package 10 and laterally propagating light from either the LED chip 12 or the lumiphoric particles 16 may be redirected in a desired emission direction. As illustrated, a portion of the wavelength conversion element 14 may be arranged to protrude above the light-altering layer 28. In this manner, a clearance may be provided to account for manufacturing variations to avoid inadvertently forming the light-altering layer 28 on a top surface of the wavelength conversion element 14. For light-reflecting embodiments, the light-altering layer 28 may have a predominantly white color. Alternatively, the light-altering layer 28 may be provided with a predominantly black color to provide increased contrast for light passing through the wavelength conversion element 14.

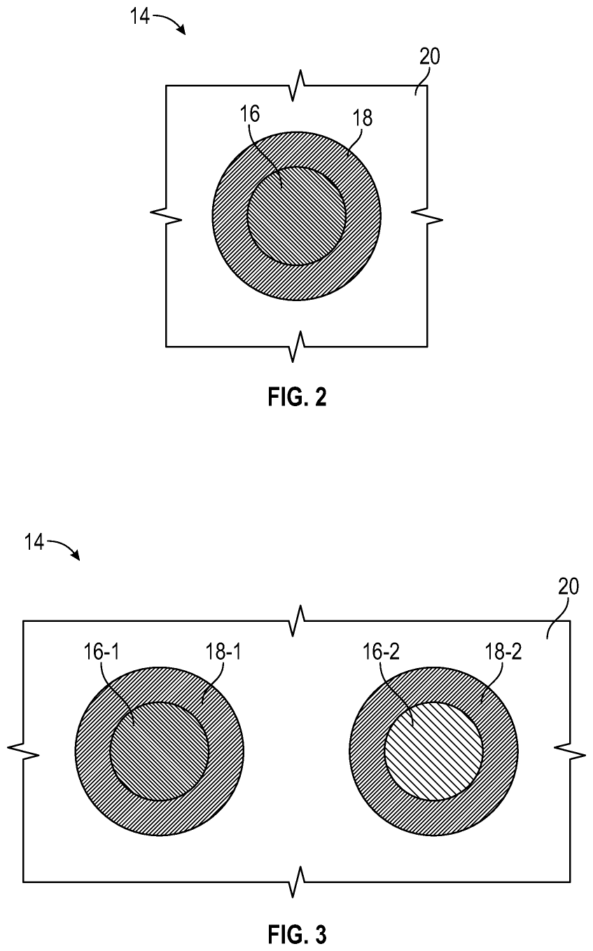

FIG. 2 is a cross-sectional view of a portion of the wavelength conversion element 14 of FIG. 1 with an individual lumiphoric particle 16 and corresponding coating 18. The lumiphoric particle 16 may be encapsulated or fully encapsulated with the coating 18 before being mixed within the host material 20 of the wavelength conversion element 14. In certain embodiments, the coating 18 may include a glass material that is similar to a glass of the host material 20. While both generally comprise glass, the coating 18 may further comprise different materials and/or dopants that locally alter the characteristics of the wavelength conversion element 14 as described above. For example, the coating 18 may form a refractive index step between the lumiphoric particle 16 and the host material 20 for increased transmission of light relative to the lumiphoric particle 16. Exemplary materials for such embodiments relative to wavelengths of light are described in U.S. application Ser. No. 17/837,680, filed Jun. 10, 2022, the disclosure of which is hereby incorporated by reference in its entirety. In another example, the coating 18 may be configured to provide a protective coating that reduces degradation of the lumiphoric particle 16 during firing of the host material 20. In another example, the coating 18 may comprise a material, such as pure silica glass, that provides increased thermal conductivity around the lumiphoric particle 16 within the host material 20. In yet another example, the coating 18 may comprise dopants that alter optical, mechanical, and/or thermal characteristics of the host material 20. In still further examples, the coating 18 of FIG. 2 may comprise a multiple-layer structure. For example, a multiple-layer structure for the coating 18 may form a progressively graded refractive index between the lumiphoric particle 16 and the host material 20. In another example, a multiple-layer structure for the coating 18 may comprise different materials for different purposes, such as one sub-layer forming a refractive index step and another sub-layer for increased thermal conductivity and/or doping.

FIG. 3 is a cross-sectional view of a portion of the wavelength conversion element 14 of FIG. 1 for embodiments that include different types of lumiphoric particles 16-1, 16-2. In one example, the lumiphoric particle 16-1 may be configured to convert a first wavelength of light from the LED chip 12 of FIG. 1 to a second wavelength of light, and the coating 18-1 is arranged to encapsulate the lumiphoric particle 16-1. The lumiphoric particle 16-2 may be configured to convert the first wavelength to a third wavelength of light that is different than the second wavelength of light, and the coating 18-2 is arranged to separately encapsulate the lumiphoric particle 16-2. Since the lumiphoric particles 16-1, 16-2 provide different optical and/or thermal characteristics, the coatings 18-1, 18-2 may advantageously be formed of different materials tailored to differently enhance the specific characteristics of the corresponding lumiphoric particles 16-1, 16-2. To form the wavelength conversion element 14 of FIG. 3, the lumiphoric particles 16-1, 16-2 and corresponding coatings 18-1, 18-2 are separately formed from one another and then mixed within the host material 20. After firing, the host material 20 is hardened to fix the lumiphoric particles 16-1, 16-2 and coatings 18-1, 18-2 in place.

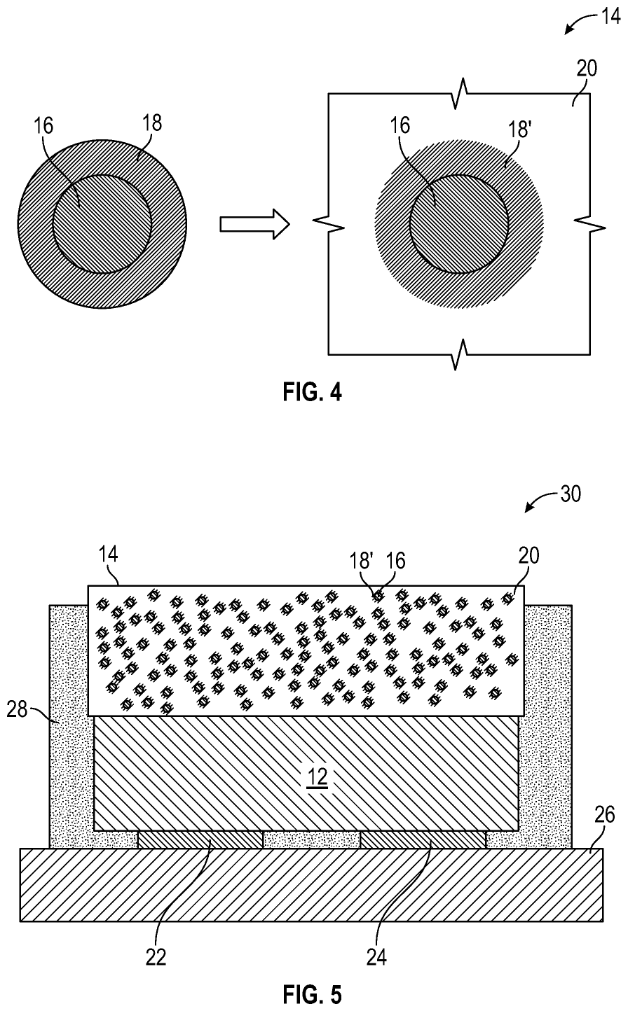

FIG. 4 is a cross-sectional view depicting embodiments where material grading of the pre-formed coating 18 is promoted when formed within the wavelength conversion element 14. The left portion of FIG. 4 is a cross-sectional view of the lumiphoric particle 16 that is encapsulated by the coating 18 as a pre-treatment before processing within the wavelength conversion element 14. As illustrated, the coating 18 forms a distinct outer boundary. In certain embodiments, the distinct outer boundary of the coating 18 may remain intact within the fully processed wavelength conversion element 14 as illustrated in FIGS. 1 and 2. In other embodiments, the distinct outer boundary may not be present in the fully processed wavelength conversion element 14 as illustrated by the right portion of FIG. 4. The right portion of FIG. 4 is a cross-sectional view of a portion of the wavelength conversion element 14 after hardening and outer boundaries of a coating 18′ are non-distinct. As described above, the wavelength conversion element 14 may be formed by mixing the lumiphoric particle 16 with the corresponding coating 18 within the host material 20, followed by a heat treatment, e.g., firing, that hardens the host material 20. The material of the coating 18 may be selected to radially diffuse into the host material 20 such that a concentration of the material decreases in a direction away from the lumiphoric particle 16. In this manner, the coating 18′ forms a graded material structure within the wavelength conversion element 14. For optical enhancements, such grading may form a graded index of refraction between the lumiphoric particle 16 and the host material 20. For thermal enhancements, the grading may effectively leave the highest concentrations of the coating 18′ proximate the lumiphoric particle 16 while avoiding sharp transitions in thermal conductivity relative to the host material 20.

FIG. 5 is a cross-sectional view of an LED package 30 that is similar to the LED package 10 of FIG. 1 for embodiments where the coatings 18′ form the graded material structures of FIG. 4. As illustrated, multiple ones of the lumiphoric particles 16 and coatings 18′ may be distributed through the wavelength conversion element 14, thereby forming multiple localized graded material regions between the lumiphoric particles 16 and the host material 20. In certain embodiments, the lumiphoric particles 16 and coatings 18′ may include different types of phosphor particles and corresponding coatings as described above for FIG. 3.

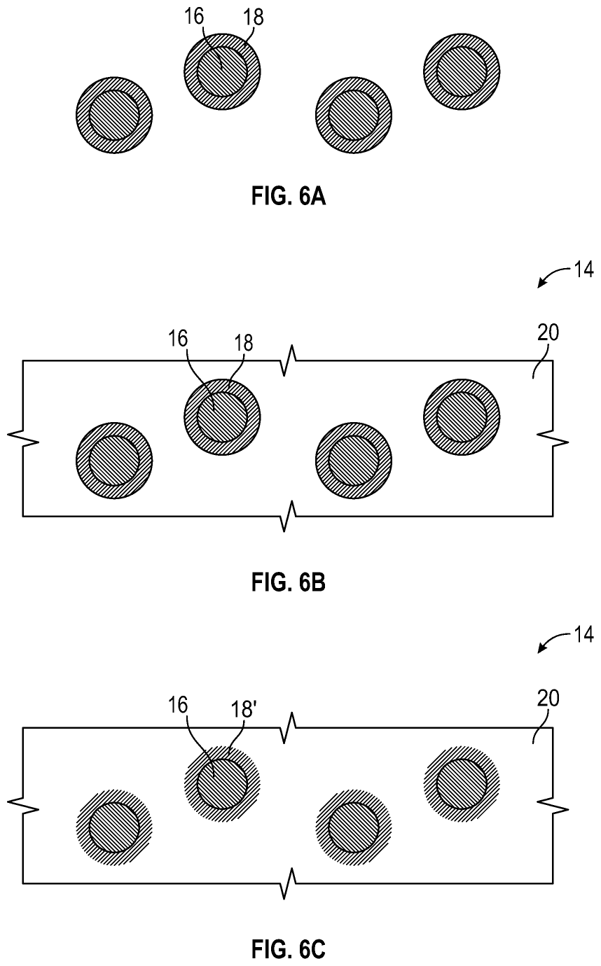

FIGS. 6A to 6C represent cross-sectional views at sequential fabrication steps in the formation of the wavelength conversion element 14 of FIG. 5. FIG. 6A is a cross-sectional view of the lumiphoric particles 16 with corresponding coatings 18 that are formed before being added to the wavelength conversion element 14. In FIG. 6B, the lumiphoric particles 16 with corresponding coatings 18 are suspended or otherwise mixed within the host material 20 as a precursor structure for the wavelength conversion element 14. In FIG. 6C, the wavelength conversion element has been hardened by, for example, a firing process as described above. As illustrated, the higher temperatures of the firing process may promote diffusion of the material of the coatings 18′ into the host material 20, thereby forming non-distinct boundaries of the coatings 18′. In this manner, the fabrication steps of FIGS. 6A to 6C may promote formation of graded material structures for the coatings 18′ within the wavelength conversion element 14. Large sheets of the wavelength conversion element 14 may be formed and fired in this manner, followed by singulation of individual wavelength conversion elements 14 sized for placement in LED packages as illustrated in FIGS. 1 and 5.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method comprising:
forming a coating of a first material on one or more lumiphoric particles;
suspending the one or more lumiphoric particles in a host material; and
firing the host material with the one or more lumiphoric particles such that the first material of the coating radially diffuses into the host material around the one or more lumiphoric particles, the host material and the one or more lumiphoric particles forming a wavelength conversion element.

2. The method of claim 1, further comprising singulating the wavelength conversion into a number of individual wavelength conversion elements.

3. The method of claim 1, wherein the first material of the coating comprises a first glass material and the host material comprises a second glass material that is different than the first glass material.

4. The method of claim 1, wherein the coating is a first coating of the first material and the one or more lumiphoric particles are one or more first lumiphoric particles, the method further comprising:
forming a second coating of a second material on one or more second lumiphoric particles;
suspending the one or more first lumiphoric particles and the one or more second lumiphoric particles in the host material; and
firing the host material with the one or more first lumiphoric particles and the one or more second lumiphoric particles to form the wavelength conversion element.

5. The method of claim 1, further comprising attaching the wavelength conversion element to a light-emitting diode (LED) chip.

6. The method of claim 5, further comprising mounting the LED chip to a submount such that the LED chip is between the wavelength conversion element and the submount.

7. The method of claim 6, further comprising forming a light-reflective or light-refractive material on the submount and laterally surrounding peripheral edges of the LED chip and the wavelength conversion element.

8. The method of claim 1, wherein the one or more lumiphoric particles comprises a plurality of lumiphoric particles and the coating surrounds at least two lumiphoric particles of the plurality of lumiphoric particles.

9. The method of claim 1, wherein firing the host material comprises vacuum drying.

10. The method of claim 1, wherein firing the host material comprises heating the host material with the one or more lumiphoric particles and the coating.

11. A light-emitting diode (LED) package comprising:
at least one LED chip, the at least one LED chip being configured to generate light in a first peak wavelength range; and
a wavelength conversion element on the at least one LED chip, the wavelength conversion element comprising a plurality of lumiphoric particles in a host material and a plurality of coatings forming intermediate materials between the plurality of lumiphoric particles and the host material, and an individual coating of the plurality of coatings surrounds at least one individual lumiphoric particle of the plurality of lumiphoric particles.

12. The LED package of claim 11, wherein the individual coating of the plurality of coatings surrounds at least two lumiphoric particles of the plurality of lumiphoric particles.

13. The LED package of claim 11, wherein each lumiphoric particle of the plurality of lumiphoric particles is surrounded by at least one coating of the plurality of coatings.

14. The LED package of claim 11, wherein neighboring lumiphoric particles of the plurality of lumiphoric particles and corresponding coatings of the plurality of coatings are separated by portions of the host material.

15. The LED package of claim 11, wherein the plurality of lumiphoric particles comprise:
a first lumiphoric particle configured to convert a first wavelength of light from the at least one LED chip to a second wavelength of light, and a first coating of the plurality of coatings is arranged to encapsulate the first lumiphoric particle; and
a second lumiphoric particle configured to convert the first wavelength of light from the at least one LED chip to a third wavelength of light that is different than the second wavelength of light, and a second coating of the plurality of coatings is arranged to encapsulate the second lumiphoric particle, wherein the second coating comprises a different material than the first coating.

16. The LED package of claim 11, wherein the plurality of coatings form graded structures within the wavelength conversion element such that a concentration of the intermediate materials decreases in directions away from each lumiphoric particle of the plurality of lumiphoric particles.

17. The LED package of claim 11, wherein the host material comprises a first glass material.

18. The LED package of claim 17, wherein the plurality of coatings comprises a second glass material that is different than the first glass material.

19. The LED package of claim 11, wherein the host material comprises a ceramic material.

20. The LED package of claim 11, further comprising a submount on which the at least one LED chip is mounted, and a light-reflective or light-refractive material on the submount and laterally surrounding peripheral edges of the at least one LED chip and the wavelength conversion element.

21. The LED package of claim 11, wherein the individual coating of the plurality of coatings comprises a multiple-layer structure on the at least one individual lumiphoric particle.
